(19) United States
(12) Patent Application Publication
(10) Pub. No.: US 2024/0244774 A1
(43) Pub. Date: Jul. 18, 2024

(54) SHELL OF ELECTRONIC DEVICE AND ELECTRONIC DEVICE

(71) Applicant: PEGATRON CORPORATION, Taipei City (TW)

(72) Inventors: Jr-Hung HUANG, Taipei City (TW); Wen-Cheng TSAI, Taipei City (TW); Ho-Ching HUANG, Taipei City (TW)

(21) Appl. No.: 18/496,263

(22) Filed: Oct. 27, 2023

(30) Foreign Application Priority Data
Jan. 16, 2023 (TW) 112101843

(51) Int. Cl. H05K 5/02

(52) U.S. Cl. CPC H05K 5/0217

(57) ABSTRACT

The present invention discloses a shell of an electronic device and an electronic device. The shell includes a shell body, a matching member, and a fixing member. The shell body is provided with a concave groove and a first through hole communicated with the concave groove. The matching member is arranged on the shell body and provided with a second through hole corresponding to the first through hole. The fixing member penetrates through the second through hole and the first through hole to fix the matching member to the shell body, and the fixing member passes through the concave groove and forms a lanyard hole with a side wall of the concave groove.

### CROSS REFERENCE TO RELATED APPLICATIONS

This application claims the priority benefit of Taiwan applications serial no. 112101843, filed on Jan. 16, 2023. The entirety of the above-mentioned patent application is hereby incorporated by reference herein and made a part of this specification.

### BACKGROUND

### Technical Field

The present invention relates to a shell, and in particular, to a shell of an electronic device and an electronic device that can be tied with a lanyard.

### Description of Related Art

In recent years, with the development of science and technology, mobile electronic devices have become essential technological commodities in the modern era. With the increasing needs of users, the revolution and progress of electronic technology are constantly promoted.

In order to facilitate user portability and other purposes, existing mobile electronic devices, such as mobile phone shells, are generally designed with a lanyard hole for attaching a lanyard. In the past, most lanyard holes were created by manufacturing a specific part, such as using sheet metal iron rings or pressure die-casting structures. This part had sufficient strength to securely attach the lanyard However, the method of manufacturing this part added to the overall cost and occupied space within the device, potentially limiting its size.

Furthermore, accommodating this specific part in the design also posed challenges for waterproofing, requiring additional considerations to meet the device's waterproofing requirements.

### SUMMARY

In view of the above issues, the purpose of the present invention is to provide a shell of an electronic device and an electronic device. Compared with the existing design, the present invention can not only meet the functional requirement of lanyard holes, but also can save the cost and space of the device.

In order to achieve the above purpose, the present invention provides a shell of an electronic device, which includes a shell body, a matching member, and a fixing member. The shell body is provided with a concave groove and a first through hole communicated with the concave groove. The matching member is arranged on the shell body and provided with a second through hole corresponding to the first through hole. The fixing member penetrates through the second through hole and the first through hole to fix the matching member to the shell body, and the fixing member passes through the concave groove and forms a lanyard hole with a side wall of the concave groove.

In an embodiment, the concave groove is located at one of four corners of the shell.

In an embodiment, the concave groove is located in one of four side edges of the shell.

In an embodiment, an extension direction of the first through hole is substantially parallel to that of the second through hole.

In an embodiment, the shell body is further provided with a fixing hole, the fixing member is further provided with an end far away from the first through hole, and the end passes through the concave groove and is fixed to the fixing hole.

In an embodiment, the fixing member is a screw or a screw bolt.

In an embodiment, the shell further includes a protecting member, and the protecting member is arranged on the matching member.

In order to achieve the above purpose, the present invention also provides an electronic device, which includes the shell of any one described above.

In an embodiment, the electronic device further includes a display surface, and extension directions of the first through hole and the second through hole are substantially parallel to a normal direction of the display surface.

In an embodiment, the electronic device is a mobile phone, a tablet computer, or a laptop computer.

According to the above, in the shell of the electronic device and the electronic device of the present invention, through the structure design that the fixing member penetrates through the second through hole of the matching member and the first through hole of the shell body to fix the matching member to the shell body, and the fixing member passes through the concave groove and forms the lanyard hole with the side wall of the concave groove, the shell and the electronic device of the present invention can not only meet the functional requirement of the lanyard hole, but also can save the cost and space of the device. At the same time, there is no need for additional design in terms of waterproofing effect.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic view of an electronic device according to an embodiment of the present invention.

FIG. 2 is a partial enlarged view of the electronic device in FIG. 1.

FIG. 3 is an exploded view of the electronic device in FIG. 2.

FIG. 4 is a partial cross-sectional view of the electronic device in FIG. 2.

### DETAILED DESCRIPTION

An electronic device according to an embodiment of the present invention will be described below with reference to related drawings in which the same elements will be illustrated with the same reference numerals. The elements present in the following embodiments are intended only to illustrate relative relationships thereof and do not represent true proportions or dimensions of the elements.

A shell of an electronic device and an electronic device according to embodiments of the present invention will be described below with reference to the relevant accompanying drawings, and the same components will be explained with the same reference numerals. The components presented in the following embodiments are only used for illustrating the relative relationships and do not represent the proportions or dimensions of the actual components.

The electronic device of the present invention may be, for example, a mobile phone, a tablet computer, a laptop computer, or other flat-panel display device. The electronic device of the following embodiments takes the mobile phone as an example.

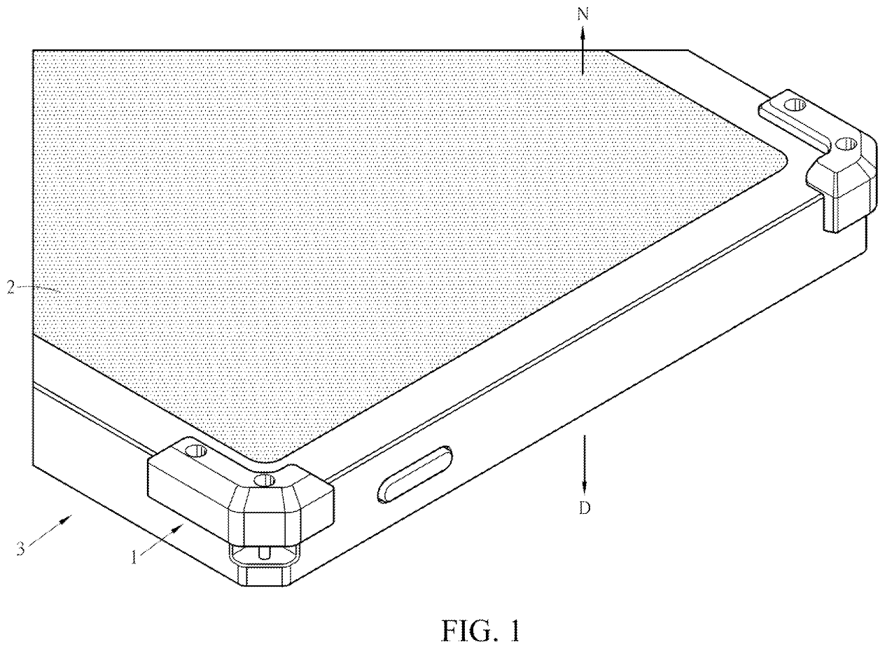

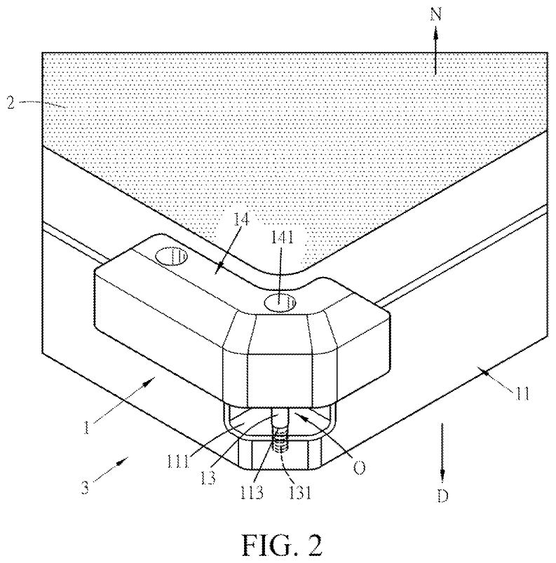

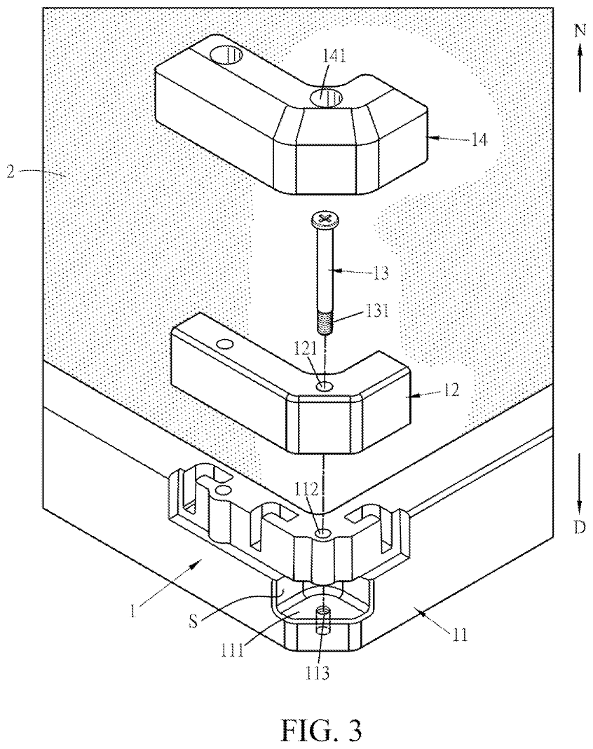

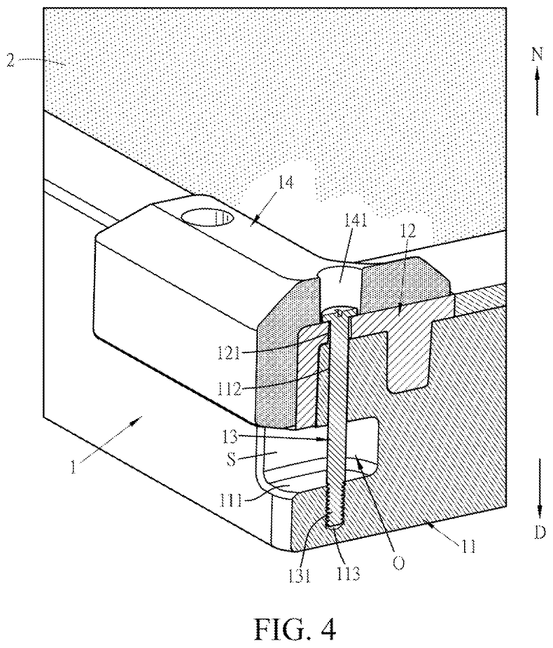

FIG. 1 is a schematic view of an electronic device according to an embodiment of the present invention; FIG. 2 is a partial enlarged view of the electronic device in FIG. 1; FIG. 3 is an exploded view of the electronic device in FIG. 2; and FIG. 4 is a partial cross-sectional view of the electronic device in FIG. 2.

Referring to FIG. 1 to FIG. 4, an electronic device 3 of the present invention includes a shell 1, and the shell 1 includes a shell body 11, a matching member 12, and a fixing member 13. In addition, the shell 1 of this embodiment may also include a protecting member 14.

The shell body 11 is roughly square in shape, and a material of the shell body may include metal or plastic. The shell body 11 is provided with a concave groove 111 and a first through hole 112 communicated with the concave groove 111. Here, the concave groove 111 is located below the first through hole 112 and in a side surface of the shell body 11. The concave groove 111 and the first through hole 112 of this embodiment are located at at least one of four corners of the shell 1, but is not limited thereto. In different embodiments, the concave groove 111 and the first through hole 112 may also be located in at least one of four side edges of the shell 1.

The matching member 12 is arranged on the shell body 11 and provided with a second through hole 121 corresponding to the first through hole 112. Here, a material of the matching member 12 maybe the same as or different from that of the shell body 11, and the matching member 12 and the shell body 11 are correspondingly arranged and connected to form an outer shell body of the electronic device. An extension direction D of the second through hole 121 of the matching member 12 is substantially parallel to and overlapped with that of the first through hole 112 of the shell body 11. In addition, the electronic device 3 of this embodiment further includes a display panel (unmarked), and the display panel has a display surface 2. Here, the shell 1 (or the shell body 11) surrounds the periphery of the display panel, and the display surface 2 is exposed from the shell 1, and the extension directions D of the first through hole 112 and the second through hole 121 are substantially parallel to a normal direction N of the display surface 2.

The fixing member 13 penetrates through the second through hole 121 and the first through hole 112 to fix the matching member 12 to the shell body 11, and the fixing member 13 passes through the concave groove 111 and forms a lanyard hole O with a side wall S of the concave groove 111. Here, a shaft of the fixing member 13 will not contact the side wall S of the concave groove 111, thus forming the lanyard hole O that allows a lanyard to pass through. As shown in FIG. 4, the fixing member 13 of this embodiment is further provided with an end 131 far away from the first through hole 112 or the second through hole 121, and the fixing member 13 maybe, for example, a screw or a screw bolt. The end 131 of the fixing member 13 passes through the concave groove 111 and is fixed to a fixing hole 113 of the shell body 11. The end 131 of the fixing member 13 of this embodiment has an external thread, and the fixing hole 113 has an internal thread, so that the end 131 can be locked in the fixing hole 113 to form the lanyard hole O. At the same time, the matching member 12 is fixed on the shell body 11.

In addition, the shell 1 of this embodiment further includes the protecting member 14, and the protecting member 14 is arranged on the matching member 12. Here, a material of the protecting member 14 maybe the same as or different from that of the shell body 11 or the matching member 12, and is connected to the matching member 12, for example, by buckling or screw locking, so as to protect the shell 1 from damages caused by collision. As shown in FIG. 3 and FIG. 4, the protecting member 14 of this embodiment is provided with a third through hole 141 corresponding to the first through hole 112 or the second through hole 121, and the fixing member 13 can directly pass through the third through hole 141 and lock the matching member 12 to the shell body 11. In different embodiments, the protecting member 14 and the matching member 12 can be simultaneously locked to the shell body 11 through the fixing member 13.

In conclusion, the electronic device 3 of this embodiment uses the fixing member 13 (such as the screw or the screw bolt) to replace the specific part design of the existing lanyard hole. Since the fixing member 13 has quite high structural strength, the matching member 12 can be directly fixed on the shell body 11, and then combined with the structure of the concave groove 111 of the shell body 11 to form the lanyard hole O, so as to not only meet the functional requirement of the lanyard hole, but also can save the cost and space of the device because no specific parts need to be manufactured additionally. At the same time, there is no need for additional design in terms of waterproofing effect.

According to the above, in the shell of the electronic device and the electronic device of the present invention, through the structure design that the fixing member penetrates through the second through hole of the matching member and the first through hole of the shell body to fix the matching member to the shell body, and the fixing member passes through the concave groove and forms the lanyard hole with the side wall of the concave groove, the shell and the electronic device of the present invention can not only meet the functional requirement of the lanyard hole, but also can save the cost and space of the device. At the same time, there is no need for additional design in terms of waterproofing effect.

The above description is only illustrative rather than restrictive. Any equivalent modifications or variations made without departing from the spirit and scope of the present invention shall be included in the attached claims.

What is claimed is:

1. A shell of an electronic device, comprising:
a shell body, provided with a concave groove and a first through hole communicated with the concave groove;
a matching member, arranged on the shell body and provided with a second through hole corresponding to the first through hole; and
a fixing member, penetrating through the second through hole and the first through hole to fix the matching member to the shell body, and the fixing member passing through the concave groove and forming a lanyard hole with a side wall of the concave groove.

2. The shell according to claim 1, wherein the concave groove is located at one of four corners of the shell.

3. The shell according to claim 1, wherein the concave groove is located in one of four side edges of the shell.

4. The shell according to claim 1, wherein an extension direction of the first through hole is substantially parallel to that of the second through hole.

5. The shell according to claim 1, wherein the shell body is further provided with a fixing hole, the fixing member is further provided with an end far away from the first through hole, and the end passes through the concave groove and is fixed to the fixing hole.

6. The shell according to claim 1, wherein the fixing member is a screw or a screw bolt.

7. The shell according to claim 1, further comprising:
a protecting member, arranged on the matching member.

8. An electronic device, comprising:
a shell, including:
a shell body, provided with a concave groove and a first through hole communicated with the concave groove;
a matching member, arranged on the shell body and provided with a second through hole corresponding to the first through hole; and
a fixing member, penetrating through the second through hole and the first through hole to fix the matching member to the shell body, and the fixing member passing through the concave groove and forming a lanyard hole with a side wall of the concave groove; and
a display surface, wherein extension directions of the first through hole and the second through hole are substantially parallel to a normal direction of the display surface.

9. The electronic device according to claim 8, wherein the electronic device is a mobile phone, a tablet computer, or a laptop computer.
